(19) United States
(12) Patent Application Publication
(10) Pub. No.: US 2006/0194383 A1
(43) Pub. Date: Aug. 31, 2006

(54) Semiconductor device and method for manufacturing the same

(75) Inventor: Juri Kato, Nagano-Ken (JP)

Correspondence Address: EDWARDS & ANGELL, LLP, P.O. BOX 55874, BOSTON, MA, 02205, US

(73) Assignee: Seiko Epson Corporation, Tokyo (JP)

(21) Appl. No.: 11/364,026

(22) Filed: Feb. 27, 2006

(30) Foreign Application Priority Data
Feb. 28, 2005 (JP) 2005-054611

(51) Int. Cl. H01L 21/8234; H01L 29/76

(52) U.S. Cl. 438/197; 257/288

(57) ABSTRACT

A semiconductor device includes: a second semiconductor layer formed on a side surface of a first semiconductor by epitaxial growth; a gate electrode disposed on a film formation surface of the second semiconductor layer; a source layer formed on the semiconductor layer and disposed on one side of the gate electrode; and a drain layer formed on the semiconductor layer and disposed on the other side of the gate electrode.

### BACKGROUND

1. Technical Field

The present invention relates to a semiconductor device and a method for manufacturing the same, which is particularly suitable for use in a field effect transistor having channels on the side walls of a semiconductor layer.

2. Related Art

As a conventional semiconductor device, there is a method for improving transistor integration while securing current drive capability by forming a fin structure of Si on a Si substrate and disposing a gate electrode along the side walls of the fin, as disclosed in Extended Abstract of the 2003 International Conference on Solid State Devices and Materials, Tokyo, 2003, pp. 280-281, a non-patent document.

However, with the conventional fin-type transistor, the fin structure that becomes the channel region is formed by dry etching using a resist pattern as a mask. Thus, when defects occur in the channel region due to damages caused by dry etching, there is a problem of degradation in the electric characteristics of the field effect transistor such as an interface level increase and a mobility decrease at the channel region.

### SUMMARY OF THE INVENTION

An advantage of the invention is to provide a semiconductor device that can have a plurality of channels on the side walls of the semiconductor layer while preventing damages in the channel region and a method for manufacturing the semiconductor device.

According to a first aspect of the invention, a semiconductor device includes: a second semiconductor layer formed on a side surface of a first semiconductor by epitaxial growth; a gate electrode disposed on a film formation surface of the second semiconductor layer; a source layer formed on the semiconductor layer and disposed on one side of the gate electrode; and a drain layer formed on the semiconductor layer and disposed on the other side of the gate electrode.

In this case, the epitaxially grown second semiconductor layer may be disposed on the side surfaces of the first semiconductor layer, and channels may lie on the film formation surface of the second semiconductor layer that is undamaged by dry etching. Because the channel region may be prevented from defects even when the channels are formed along the side surfaces of the first semiconductor layer, it is possible to prevent the interface level increase as well as the mobility decrease at the channel region. As a result, the transistor integration may be improved while securing the current drive capability, and stable and good electric characteristics may be acquired.

It is preferable that the first semiconductor layer is a single crystal SiₓGe₁₋ₓ or a single crystal SiₓGe_{y}C_{1-x-y}, and the second semiconductor layer is a single crystal Si.

In this case, lattice matching between the first and the second semiconductor layers becomes possible, and the second semiconductor layer having good crystal quality may be formed on the first semiconductor layer.

It is preferable that the first semiconductor layer is a relaxed single crystal SiₓGe₁₋ₓ or a single crystal SiₓGe_{y}C_{1-x-y}, and the second semiconductor layer is a distorted single crystal Si.

In this case, the second semiconductor layer may be distorted by forming the second semiconductor layer on the first semiconductor layer, and the transistor mobility may be increased while making the manufacturing process less complicated.

According to a second aspect of the invention, a semiconductor device includes: a semiconductor layer disposed on a side surface of an insulator layer and formed by epitaxial growth; a gate electrode formed on a film formation surface of the semiconductor layer; a source layer formed on the semiconductor layer and disposed on one side of the gate electrode; and a drain layer formed on the semiconductor layer and disposed on the other side of the gate electrode.

In this case, the epitaxially grown semiconductor layer may be disposed on the side surfaces of the insulator layer without using a silicon-on insulator (SOI), and the channels may lie on the film formation surface of the semiconductor layer that is undamaged by dry etching. Further, if a plurality of channels are formed on the film formation surface of the semiconductor layer disposed on the side surfaces of the insulator film, the current drive capability increases. As a consequence, the SOI transistor integration may be improved while securing the current drive capability, and stable and good electric characteristics may be acquired at reduced cost.

According to a third aspect of the invention, a method for manufacturing a semiconductor device includes: exposing a side surface of a first semiconductor layer by patterning the first semiconductor layer formed on an insulator; forming a second semiconductor layer on the side surface of the first semiconductor layer by epitaxial growth; forming a gate electrode on a film formation surface of the second semiconductor layer; and forming a source layer disposed on one side of the gate electrode and a drain layer disposed on the other side of the gate electrode on the second semiconductor layer.

In this case, the epitaxially grown second semiconductor layer may be disposed on the side surfaces of the first semiconductor layer, and the channels may lie on the film formation surface of the second semiconductor layer undamaged by dry etching. As a consequence, the transistor integration may be improved while securing the current drive capability, and stable and good electric characteristics may be acquired.

According to a fourth aspect of the invention, a method for manufacturing a semiconductor device includes: relaxing a first semiconductor layer formed on an insulator; exposing a side surface of the first semiconductor layer by patterning the first semiconductor layer; forming a second semiconductor layer by epitaxial growth on a side surface of the relaxed first semiconductor layer; forming a gate electrode on a film formation surface of the second semiconductor layer; and forming a source layer disposed on one side of the gate electrode and a drain layer disposed on the other side of the gate electrode on the second semiconductor layer.

In this case, while the second semiconductor layer may be distorted, the epitaxially grown second semiconductor layer may be disposed on the side surfaces of the first semiconductor layer, and the channels may lie on the film formation surface of the second semiconductor layer that is undamaged by dry etching. Consequently, the transistor integration may be improved while securing the current drive capability, and stable and good electric characteristics may be acquired.

The method for manufacturing the semiconductor device may further include: attaching the insulator formed on the first semiconductor substrate to the first semiconductor layer formed on the second semiconductor substrate; and forming the first semiconductor layer formed on the insulator by removing the second semiconductor substrate having the first semiconductor layer formed thereon, after attaching the insulator to the first semiconductor layer.

In this case, the first semiconductor layer having a composition different from that of the first semiconductor substrate may be formed on the first semiconductor substrate, and the first semiconductor layer may be easily relaxed by heat processing the first semiconductor layer formed on the insulator. As a consequence, the second semiconductor layer may be distorted when formed on the first semiconductor layer, and the transistor mobility may be improved while making the manufacturing process less complicated.

According to a fifth aspect of the invention, a method for manufacturing a semiconductor device includes: forming a first semiconductor layer on a semiconductor substrate by epitaxial growth; exposing a side surface of the first semiconductor layer by selectively etching the first semiconductor layer; forming a second semiconductor layer having an etching rate lower than that of the first semiconductor layer on the first semiconductor layer having the side surface formed thereon; forming a support which is composed of a material whose etching rate is lower than that of the first semiconductor layer and which supports the second semiconductor layer on the semiconductor substrate; forming an exposure portion that exposes a part of the first semiconductor layer from the second semiconductor layer; forming a cavity between the semiconductor substrate and the second semiconductor layer by selectively etching and removing the first semiconductor layer via the exposure portion; forming a filling insulator layer filled in the cavity; forming a gate electrode on a film formation surface of the second semiconductor layer disposed on the side surface of the first semiconductor layer; and forming a source layer disposed on one side of the gate electrode and a drain layer disposed on the other side of the gate electrode on the second semiconductor layer.

In this case, the second semiconductor layer may be epitaxially grown on the side surfaces of the first semiconductor layer, the second semiconductor layer may be bent in a vertical direction, and an etching selection ratio between the second and first semiconductor layers may be secured. As a consequence, it becomes possible to selectively etch the first semiconductor layer while preventing the second semiconductor layer formed on the surface side of the first semiconductor layer from being etched, and to form the cavity below the vertically bent second semiconductor layer. Further, by disposing a support for supporting the second semiconductor layer on the semiconductor substrate, the vertically bent second semiconductor layer may be prevented from being sagged even when the cavity is formed below the second semiconductor layer. Moreover, this cavity below the second semiconductor layer may be filled with the insulator film by a CVD method or a thermal oxidation method. Thus, it is possible to dispose the vertically bent second semiconductor layer on the insulator film while restraining the occurrence of defects in the second semiconductor layer, to insulate the second semiconductor layer from the semiconductor substrate without damaging the quality of the second semiconductor layer, and to extend the channels in a vertical direction with relative to the semiconductor substrate. As a result, it is possible to dispose, on the insulator, the transistor having the channels on the side walls of the semiconductor layer, to improve the SOI transistor integration while securing the current drive capacity, and to acquire stable and good electric characteristics at reduced cost without using the SOI substrate.

According to a sixth aspect of the invention, a method for manufacturing a semiconductor device includes: forming a first semiconductor layer on a semiconductor substrate by epitaxial growth; forming a second semiconductor layer disposed on a partial region of the first semiconductor layer by selective epitaxial growth; forming a third semiconductor layer having an etching rate lower than those of the first and second semiconductor layers on the second semiconductor layer by selective epitaxial growth so as to cover a side surface of the second semiconductor layer; forming a support which is composed of a material whose etching rate is lower than those of the first and second semiconductor substrates and which supports the third semiconductor layer on the semiconductor substrate; forming an exposure portion that exposes a part of the first or the second semiconductor layer from the third semiconductor layer; forming a cavity between the semiconductor substrate and the third semiconductor layer by selectively etching and removing the first and second semiconductor layers via the exposure; forming a filing insulator layer filled in the cavity; forming a gate electrode on a film formation surface of the third semiconductor layer formed on the side surface of the second semiconductor layer; and forming a source layer disposed on one side of the gate electrode and a drain layer disposed on the other side of the gate electrode on the third semiconductor layer.

In this case, the third semiconductor layer may be epitaxially grown on the side surfaces of the second semiconductor layer. At the same time, the third semiconductor layer may be bent in a vertical direction, and to an etching selection ratio between the first and second semiconductor layers and third semiconductor layer may be secured. As a consequence, it becomes possible to selectively etch the first and second semiconductor layers while preventing the third semiconductor layer formed on the surface side of the second semiconductor layer from being etched, and to form the cavity below the vertically bent third semiconductor layer. Further, by disposing a support for supporting the third semiconductor layer on the semiconductor substrate, the vertically bent third semiconductor layer may be prevented from being sagged even when the cavity is formed below the third semiconductor layer. Thus, it becomes possible to dispose the vertically bent third semiconductor layer on the insulator film while restraining the occurrence of defects in the third semiconductor layer, to insulate the third semiconductor layer from the semiconductor substrate without damaging the quality of the third semiconductor layer, and to extend the channels in a vertical direction with relative to the semiconductor substrate. As a result, it is possible to dispose, on the insulator, the transistor having the channels on the side walls of the semiconductor layer, to improve the SOI transistor integration while securing the current drive capacity, and to acquire stable and good electric characteristics at reduced cost without using the SOI substrate.

### BRIEF DESCRIPTION OF THE DRAWINGS

The invention will be described with reference to the accompanying drawings, wherein like numbers reference like elements.

FIGS. 1A and 1B are cross-sectional diagrams showing a method for manufacturing a semiconductor device of a first embodiment of the invention.

FIGS. 2A through 2C are diagrams showing the method for manufacturing the semiconductor device of the first embodiment of the invention.

FIGS. 3A through 3C are diagrams showing the method for manufacturing the semiconductor device of the first embodiment of the invention.

FIGS. 4A through 4C are diagrams showing the method for manufacturing the semiconductor device of the first embodiment of the invention.

FIGS. 5A through 5C are diagrams showing the method for manufacturing the semiconductor device of the first embodiment of the invention.

FIGS. 6A through 6C are diagrams showing the method for manufacturing the semiconductor device of a second embodiment of the invention.

FIGS. 7A through 7C are diagrams showing the method for manufacturing the semiconductor device of the second embodiment of the invention.

FIGS. 8A through 8C are diagrams showing the method for manufacturing the semiconductor device of the second embodiment of the invention.

FIGS. 9A through 9C are diagrams showing the method for manufacturing the semiconductor device of the second embodiment of the invention.

FIGS. 10A through 10C are diagrams showing the method for manufacturing the semiconductor device of the second embodiment of the invention.

FIGS. 11A through 11C are diagrams showing the method for manufacturing the semiconductor device of the second embodiment of the invention.

FIGS. 12A through 12C are diagrams showing the method for manufacturing the semiconductor device of the second embodiment of the invention.

FIGS. 13A through 13C are diagrams showing the method for manufacturing the semiconductor device of the second embodiment of the invention.

FIGS. 14A through 14C are diagrams showing the method for manufacturing the semiconductor device of the second embodiment of the invention.

FIGS. 15A through 15C are diagrams showing the method for manufacturing the semiconductor device of the second embodiment of the invention.

FIGS. 16A through 16C are diagrams showing the method for manufacturing the semiconductor device of the second embodiment of the invention.

### DESCRIPTION OF THE EMBODIMENTS

The semiconductor device and the manufacturing method therefore according to the embodiments of the invention will now be described with reference to the drawings.

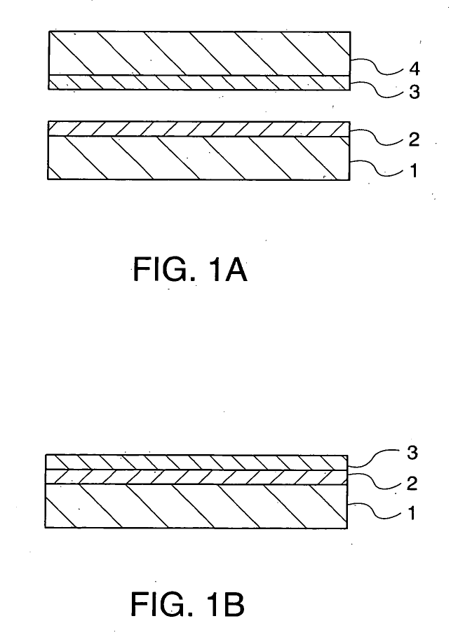

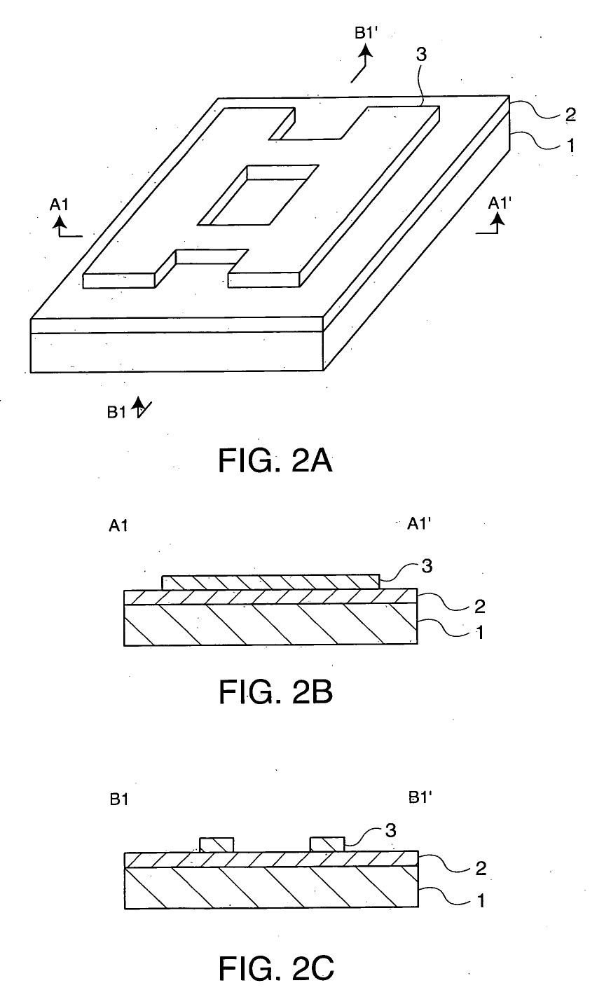

FIGS. 1A and 1B are cross-sectional diagrams illustrating the method for manufacturing the semiconductor device of the first embodiment of the invention. FIGS. 2A, 3A, 4A and 5A are perspective diagrams illustrating the method for manufacturing the semiconductor device of the first embodiment of the invention. FIGS. 2B, 3B, 4B and 5B are cross-sectional diagrams taken on lines A1-A1′ through A4-A4′ of FIGS. 2A, 3A, 4A and 5A, respectively. FIGS. 2C, 3C, 4C and 5C are cross-sectional diagrams taken on lines B1-B1′ through B4-B4′ of FIGS. 2A, 3A, 4A and 5A, respectively.

In FIG. 1A, an insulator layer 2 is formed on a semiconductor substrate 1, and a first semiconductor layer 3 is epitaxially grown on a semiconductor substrate 4. Further, the first semiconductor layer 3 may use a material having a different composition from that of the semiconductor substrates 1 and 4. Materials for the semiconductor substrates 1 and 4 and the first semiconductor layer 3 can be in combination selected from, for example, Si, Ge, SiGe, SiGeC, SiC, SiSn, PbS, GaAs, InP, GaP, GaN, and ZnSe. In particular, if Si is used for the semiconductor substrates 1 and 4, it is preferable to use SiGe or SiGeC for the first semiconductor layer 3.

Then, after attaching the insulator layer 2 formed on the semiconductor substrate 1 to the first semiconductor layer 3 formed on the semiconductor substrate 4, as shown in FIG. 1B, the semiconductor substrate 4 on the first semiconductor layer 3 is removed so as to expose the surface of the first semiconductor layer 3. Further, after the removal the semiconductor substrate 4 off the semiconductor layer 3, the semiconductor layer 3 may be relaxed by being subjected to a heat process.

Next, as shown in FIGS. 2A through 2C, the side surfaces of the first semiconductor layer 3 are exposed by patterning the first semiconductor layer 3 using photolithography and etching techniques. Additionally, when exposing the side surfaces of the first semiconductor layer 3, a removed region on the first semiconductor layer 3 can correspond to an element separation region, and a remaining region on the first semiconductor layer 3 can correspond to a transistor formation region.

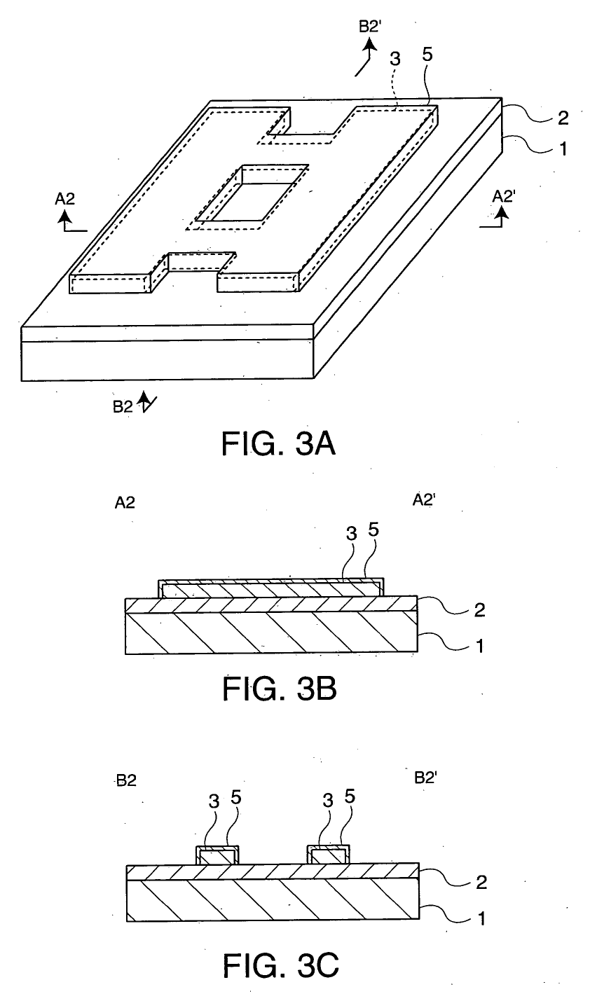

Then, as shown in FIGS. 3A through 3C, a second semiconductor layer 5 is formed by selective epitaxial growth on the first semiconductor layer 3. In this case, because the second semiconductor layer 5 cannot be formed on the insulator layer 2 by selective epitaxial growth, the second semiconductor layer 5 can be formed only on the side and upper surfaces of the first semiconductor layer 3. Further, the material for the second semiconductor layer 5 can be selected from, for example, Si, Ge, SiGe, SiGeC, SiC, SiSn, PbS, GaAs, InP, GaP, GaN, and ZnSe. In particular, if SiGe or SiGeC is used for the first semiconductor layer 3, it is preferable to use Si for the second semiconductor layer 5. As a consequence, the lattice matching between the first semiconductor layer 3 and the second semiconductor layer 5 becomes possible, and the second semiconductor layer 5 having good crystal quality can be formed on the first semiconductor layer 3.

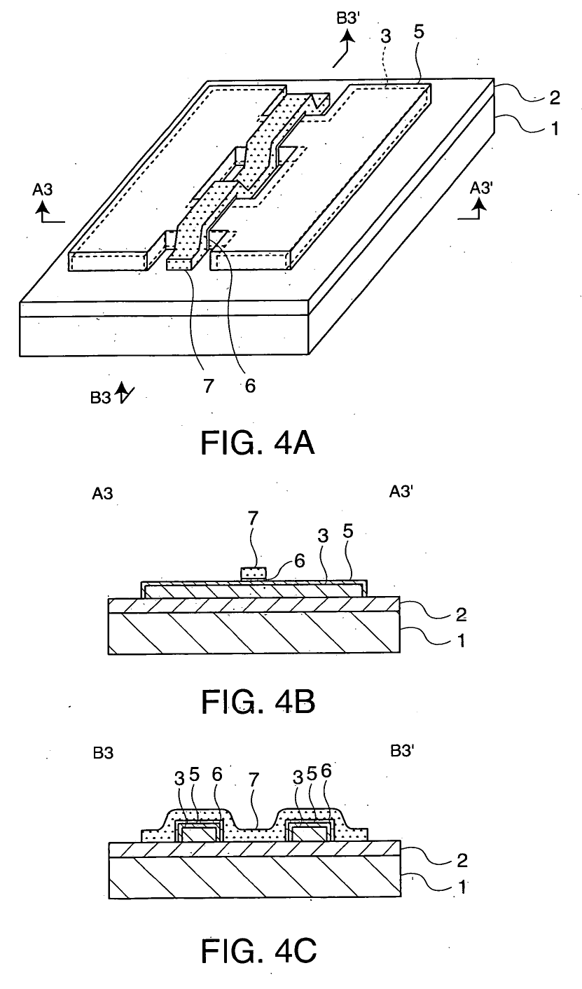

Thereafter, as shown in FIGS. 4A through 4C, a gate insulating film 6 is formed on the surface of the second semiconductor layer 5 by subjecting the surface of the second semiconductor layer 5 to thermo oxidation or CVD treatment. Then, by a method such as CVD, a polycrystalline silicon layer is formed on the second semiconductor layer 5 having the gate insulator film 6 formed thereon. Then, a gate electrode 7 is formed on the insulator layer 2 by patterning the polycrystalline silicon layer using the photolithography and etching techniques so as to bridge over the second semiconductor layer 5 via the side walls of the second semiconductor layer 5.

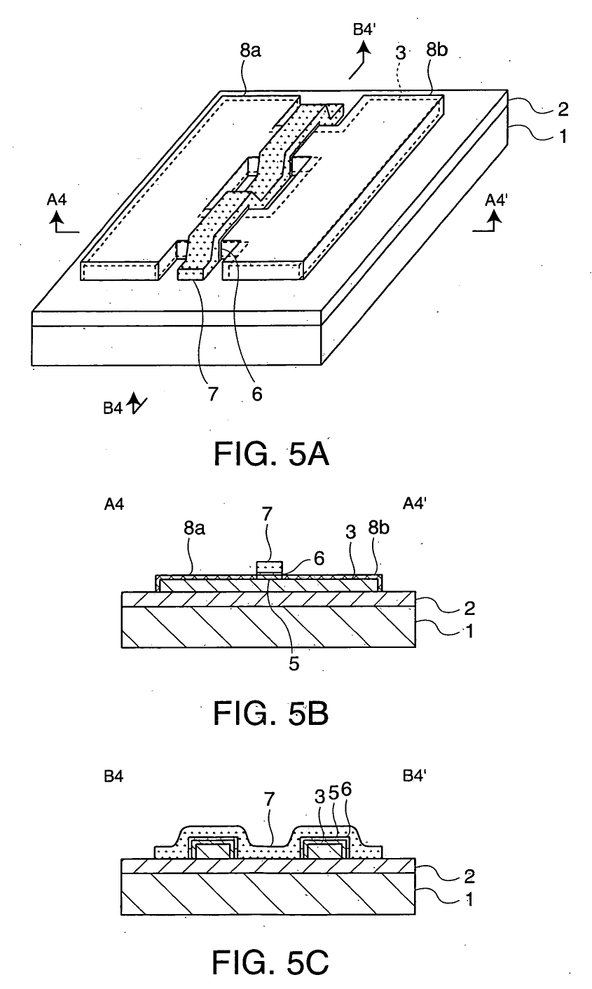

Thereafter, as shown in FIGS. 5A through 5C, by using the gate electrode 7 as a mask and implanting impurity ions such as As, P, or B in the second semiconductor layer 5, source/drain layers 8a and 8b arranged on both sides of the gate electrode 7 are formed on the second semiconductor layer 5.

Consequently, the epitaxially grown second semiconductor layer 5 can be disposed on the side surfaces of the first semiconductor layer 3, and the channels can lie on the film formation surface of the second semiconductor layer 5 that is undamaged by dry etching. Because the channel region can be prevented from defects even when the channels are formed along the side surfaces of the first semiconductor layer 3, it is possible to prevent the interface level from increasing and the mobility from decreasing at the channel region. As a result, the transistor integration can be improved while securing the current drive capability, and stable and good electric characteristics can be acquired.

Further, by relaxing the first semiconductor layer 3, the second semiconductor layer 5 formed on the first semiconductor layer 3 can be distorted, and the mobility of the transistor to be formed on the second semiconductor layer 5 can increase while making the manufacturing process less complicated.

In addition, although the method for forming the SOI transistor on the second semiconductor 5 is described in this embodiment as an example, the method may be applied for forming a thin film transistor (TFT).

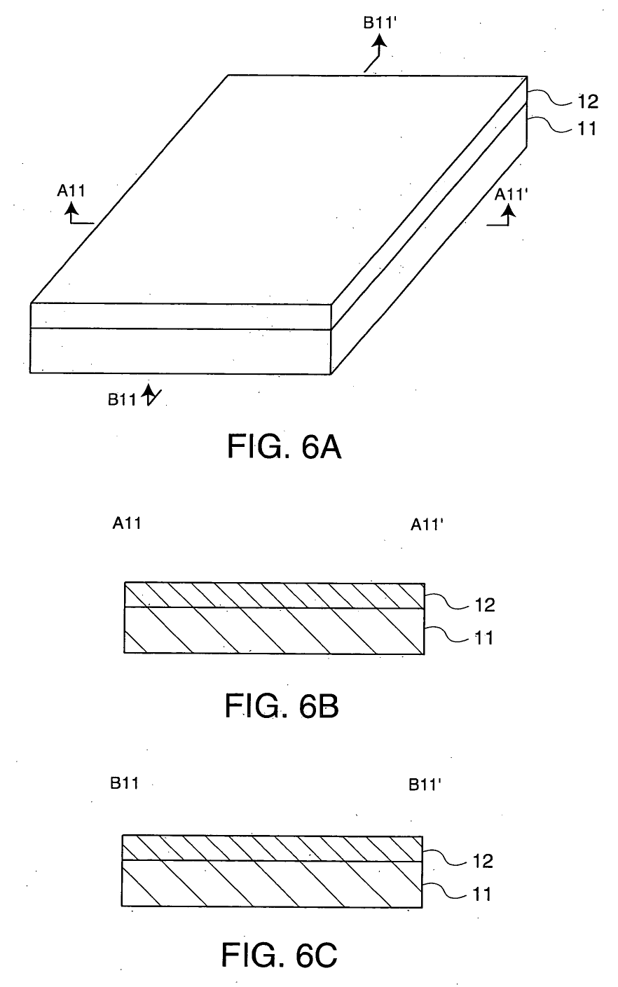

FIGS. 6A through 16A are perspective diagrams illustrating the method for manufacturing the semiconductor device of the second embodiment of the invention. FIGS. 6B through 16B are cross-sectional diagrams taken on lines A11-A11′ through A21-A21′ of FIGS. 6A through 6A, respectively. FIGS. 6C through 16C are cross-sectional diagrams taken on lines B11-B11′ through B21-B21′ of FIGS. 6A through 16A, respectively.

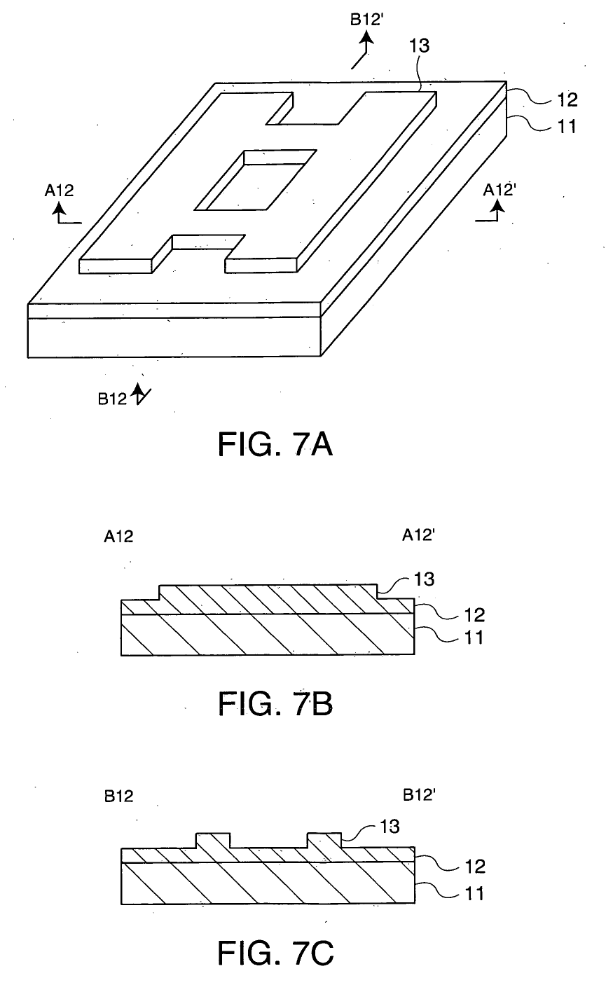

In FIGS. 6A through 6C, a first semiconductor layer 12 is formed on a semiconductor substrate 11 by epitaxial growth. Then, as shown in FIGS. 7A through 7C, a level difference 13 that exposes the side surfaces of the first semiconductor layer 12 is formed on the first semiconductor layer 12 by half-etching the first semiconductor layer 12 using the photolithography and etching techniques.

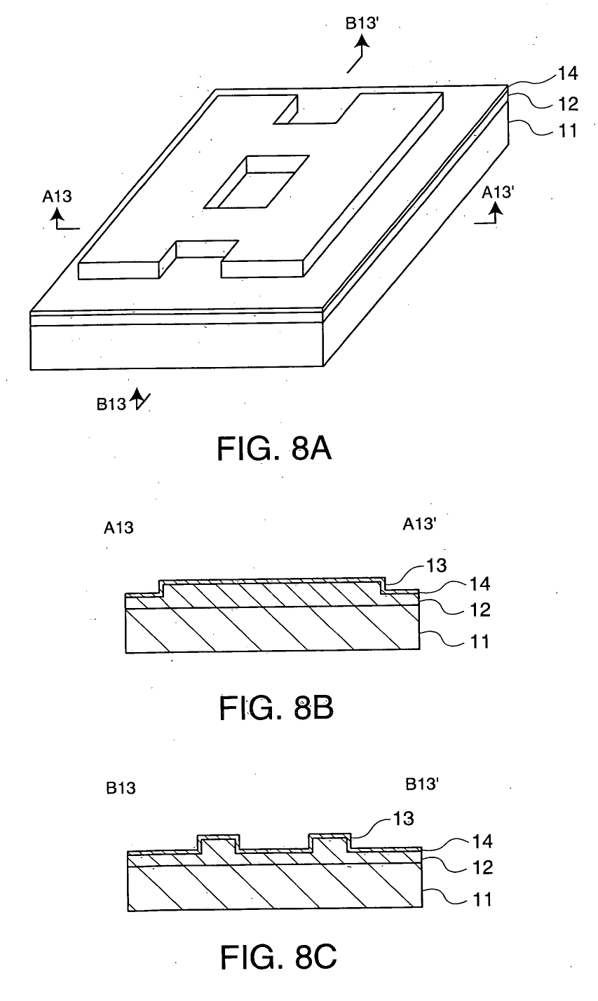

Next, as shown in FIGS. 8A through 8C, a second semiconductor layer 14 is formed by epitaxial growth on the first semiconductor layer 12 having the formed level difference 13. For the first semiconductor layer 12, a material whose etching rate is higher than those of the semiconductor substrate 11 and the second semiconductor layer 14 can be used. Materials for the semiconductor substrate 11 and the first and second semiconductor layers 12 and 14 can be in combination selected from, for example, Si, Ge, SiGe, SiC, SiSn, PbS, GaAs, InP, GaP, GaN, and ZnSe. In particular, if Si is used for the semiconductor substrate 11, it is preferable to use SiGe for the first semiconductor layer 12 and Si for the second semiconductor layer 14. Accordingly, the lattice matching between the first and second semiconductor layers 12 and 14 becomes possible, and the selection ratio between the first and second semiconductor layers 12 and 14 can be secured. Additionally, for the first semiconductor layer 12, a polycrystalline semiconductor layer, an amorphous semiconductor layer, or a porous semiconductor layer may be used other than the single-crystal semiconductor layer. Further, instead of the first semiconductor layer 12, a metal oxide film such as a Y-aluminum oxide film that can be formed by epitaxially growing the single-crystal semiconductor layer may be used.

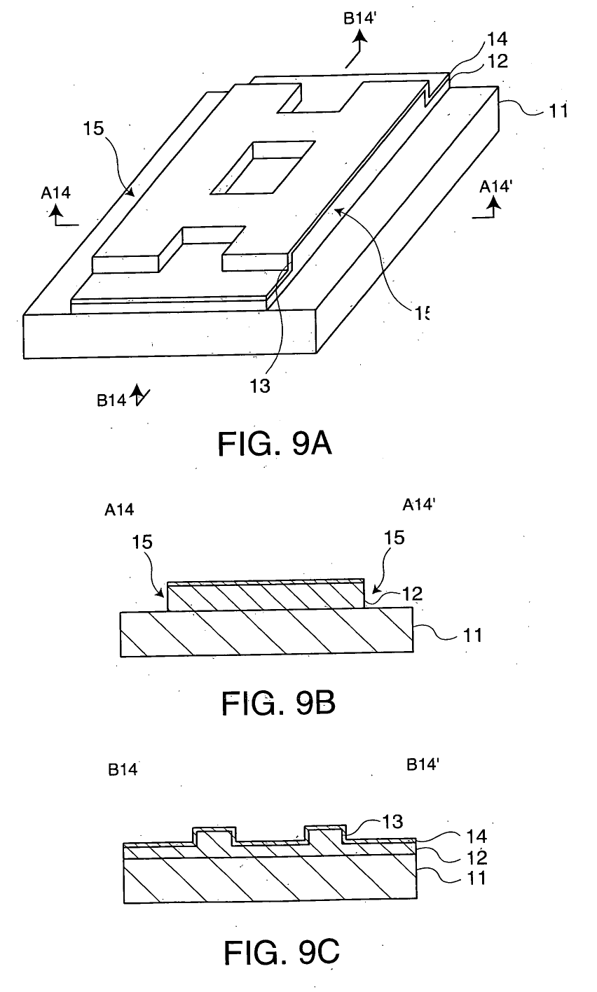

Next, as shown in FIGS. 9A through 9C, an exposure surface 15 for exposing the side walls of the second and first semiconductor layers 14 and 12 is formed by patterning the second and first semiconductor layers 14 and 12 using the photolithography and etching techniques. Further, when patterning the second and first semiconductor layers 14 and 12, in order to protect the second semiconductor layer 14, an oxidation film may be formed on the surface of the second semiconductor layer 14 by subjecting the second semiconductor layer 14 to heat oxidation or CVD. Also, when forming the exposure surface 15 that exposes the side walls of the second and first semiconductor layers 14 and 12, the etching may be stopped at the surface of the semiconductor substrate 11, or the semiconductor substrate 11 may be over-etched to create a dented portion in the semiconductor substrate 11. Further, the exposure surface of the semiconductor substrate 11 can correspond to the element separation region of the second semiconductor layer 14.

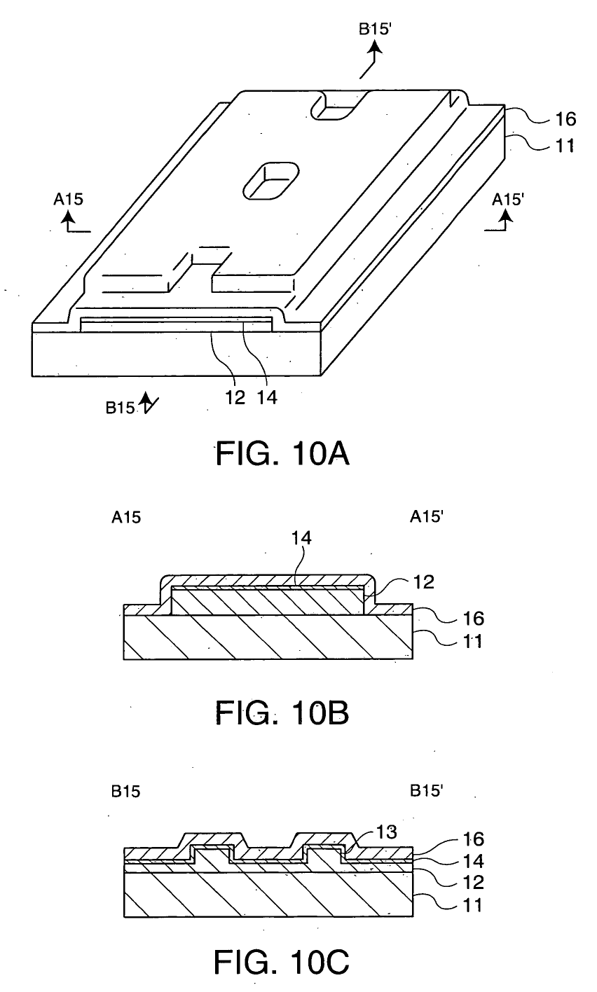

Thereafter, as shown in FIGS. 10A through 10C, a support 16 disposed to cover the exposure surface 15 is formed on the entire surface of the semiconductor substrate 11 by a method such as CVD. As the material for the support 16, an insulator of silicon oxide film or silicon nitride film may be used. Alternatively, as the material for the support 16, a semiconductor of polycrystalline silicon or single-crystal silicon may be used.

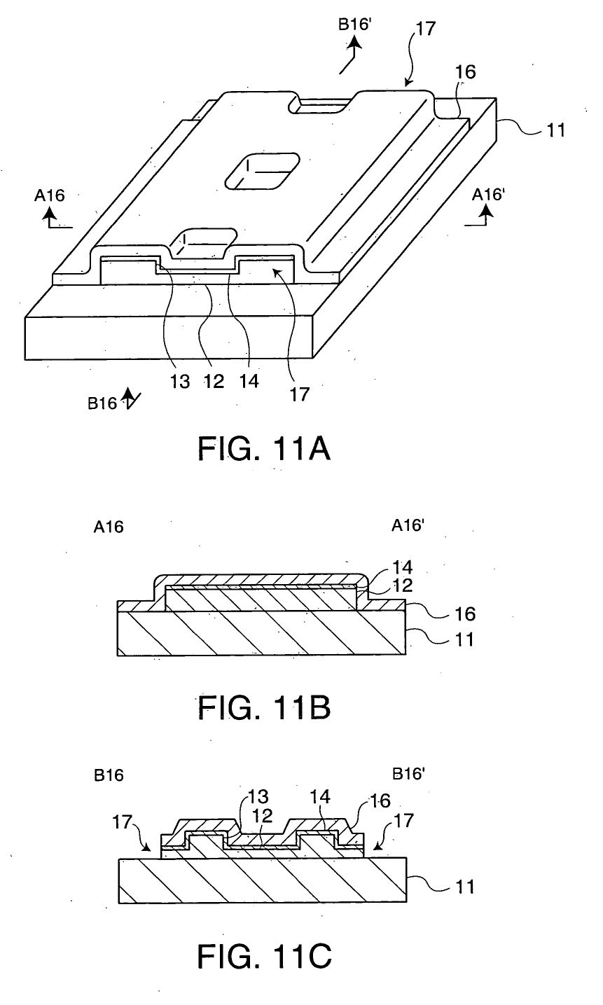

Next, as shown in FIGS. 11A through 11C, an exposure surface 17 that exposes a portion of the first semiconductor layer 12 is formed by patterning the support 16 as well as the second and first semiconductor layers 14 and 12 by the photolithography and etching techniques. The position of the exposure surface 17 can correspond to a border between the second semiconductor layer 14 and the element separation region.

Further, when exposing the portion of the first semiconductor layer 12, the etching may be stopped at the surface of the first semiconductor layer 12, or the first semiconductor layer 12 may be over-etched to create a dented portion in the first semiconductor layer 12. Alternatively, the first semiconductor layer 12 may be penetrated in order to expose the surface of the semiconductor substrate 11. In this case, by stopping the etching of the first semiconductor layer 12 in the middle of the way, the surface of the semiconductor substrate 11 can be prevented from exposing. Thus, when etching and removing the first semiconductor layer 12, it is possible to reduce the time required to treat the semiconductor substrate 11 with an etching solution or an etching gas and, thus, to prevent the semiconductor substrate 11 from being over-etched.

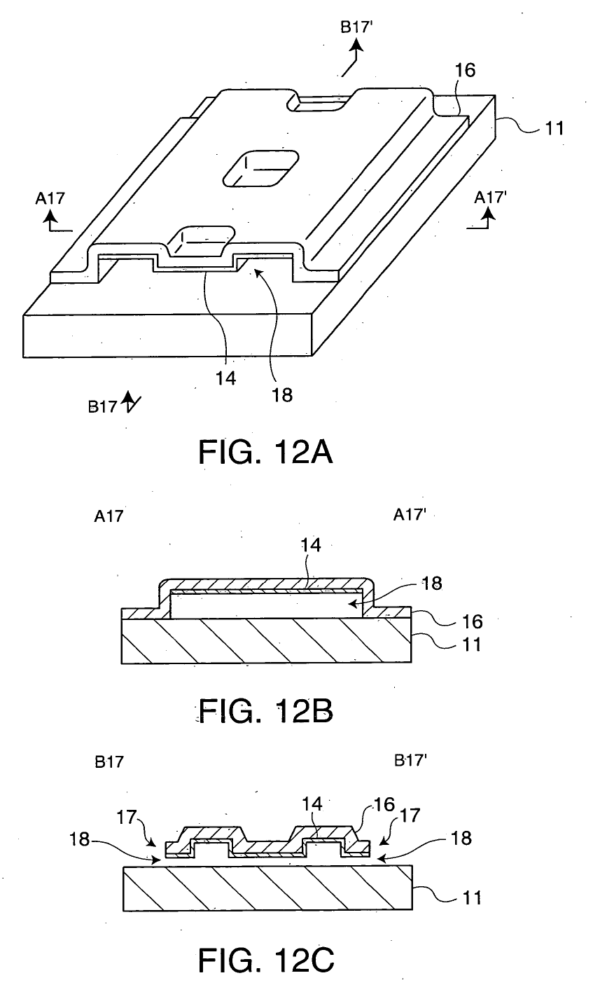

Next, as shown in FIGS. 12A through 12C, by bringing the first semiconductor layer 12 into contact with the etching gas or the etching solution via the exposure surface 17, the first semiconductor layer 12 is etched and removed, and a cavity 18 is formed between the semiconductor substrate 11 and the second semiconductor layer 14.

In this case, by forming the level difference 13 that exposes the side surfaces of the first semiconductor layer 12 on the first semiconductor layer 12, it becomes possible to epitaxially grow the second semiconductor layer 14 on the side surfaces of the first semiconductor layer 12, to bend the second semiconductor layer 14 in a vertical direction, and to secure the etching selection ratio between the second and first semiconductor layers 14 and 12. As a consequence, it becomes possible to selectively etch the first semiconductor layer 12 while preventing the second semiconductor layer 14 formed on the surface side of the first semiconductor layer 12 from being etched, and to form the cavity 18 below the vertically bent second semiconductor layer 14.

Further, by disposing the support 16 for supporting the second semiconductor layer 14 on the semiconductor substrate 11, it becomes possible to prevent the vertically bent second semiconductor layer 14 from being sagged even when the cavity 18 is formed below the second semiconductor layer 14. Accordingly, the vertically bent second semiconductor layer 14 can be disposed on the insulator film while restraining the occurrence of defects in the second semiconductor layer 14, and the second semiconductor layer 14 can be insulated from the semiconductor substrate 11 without damaging the quality of the second semiconductor layer 14. At the same time, it becomes possible to expand the surface area of the second semiconductor layer 14 that can be formed on the insulator layer without increasing the chip size, and to form the second semiconductor layer 14 having good crystal quality on the insulator film at low cost.

Moreover, by disposing the exposure surface 17, separate from the exposure surface 15, the first semiconductor layer 12 below the second semiconductor layer 14 can be brought into contact with the etching gas or the etching solution even when the support 16 for supporting the second semiconductor layer 14 on the semiconductor substrate 11 is formed. Accordingly, the vertically bent second semiconductor layer 14 can be insulated from the semiconductor substrate 11 without damaging the quality of the second semiconductor layer 14.

In addition, when the semiconductor substrate 11 and the second semiconductor layer 14 are Si, and the first semiconductor layer 12 is SiGe, it is preferable to use fluoronitric acid (a mixed solution of hydrofluoric acid, nitric acid, and water) as the solution to etch the first semiconductor layer 12. This enables the selection ratio of Si to SiGe to be about 1:100-1000, and the first semiconductor layer 12 can be removed while preventing the semiconductor substrate 11 and the second semiconductor layer 14 from being over-etched. Further, as the solution for etching the first semiconductor layer 12, fluoronitric acid hydrogen peroxide water, ammonia hydrogen peroxide water, or fluoroacetic acid hydrogen peroxide water may be used.

Further, prior to the etching and removing of the first semiconductor layer 12, the first semiconductor layer 12 may be made porous by a method such as anodization or be converted into amorphous by implanting ions to the first semiconductor layer 12. As a consequence, the etching rate of the first semiconductor layer 12 can be increased, and the etching area of the first semiconductor layer 12 can be expanded.

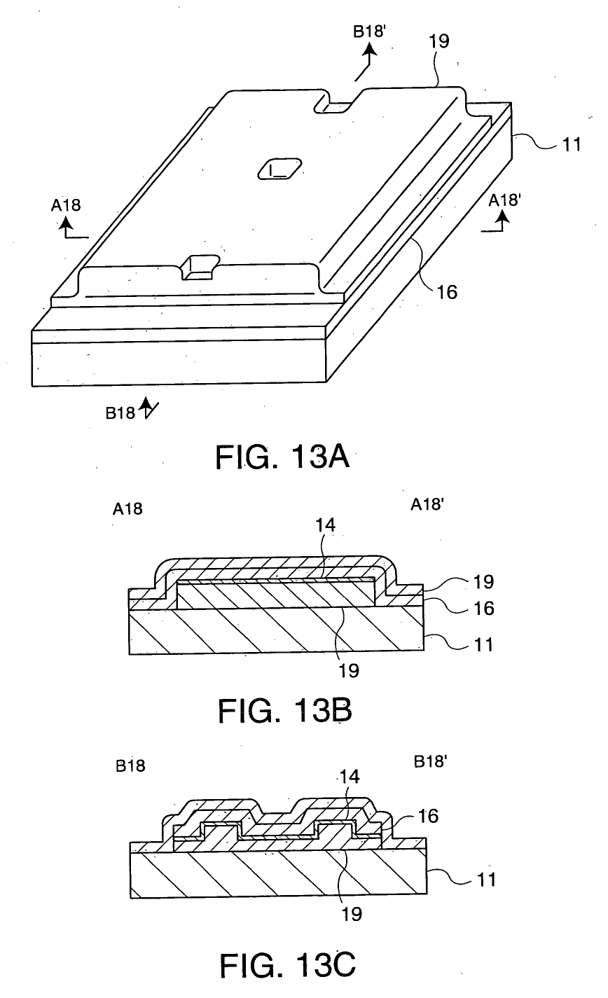

Next, as shown in FIGS. 13A through 13C, an insulator film 19 is deposited by a method such as CVD on the entire surface of the semiconductor substrate 11 so as to fill the cavity 18 below the second semiconductor layer 14.

As a consequence, the insulator film 19 can be formed under the vertically bent second semiconductor layer 14, and the epitaxially grown second semiconductor layer 14 can be disposed on the insulator film 19. Thus, the surface area of the second semiconductor layer 14 can be easily expanded, and the second semiconductor layer 14 having good crystal quality can be formed on the insulator film 19 at low cost. Further, as the insulator film 19, a fluorosilicade glass (FSG) film or a silicon nitride film may be used other than a silicon oxide film. Alternatively, as the insulator film 19, other than a spin-on-glass (SOG) film, an organic low-k film such as a PSG film, BPSG film, poly aryleneether (PAE) based film, hydrogen silisesquioxane (HSQ) based film, methyl silsesquioxane (MSQ) based film, PCB based film, CF based-film, SiOC based film, and a SiOF based film, or a porous film of these films may be used.

Then, by filling the insulator film 19 in the cavity 18 between the semiconductor substrate 11 and the second semiconductor layer 14 by the CVD method, it becomes possible to prevent the second semiconductor layer 14 from thinning and to fill the cavity 18 between the semiconductor substrate 11 and the second semiconductor layer 14 with a material other than the oxide film. Accordingly, it becomes possible to thicken the insulator film disposed at the back surface of the second semiconductor layer 14, to decrease the dielectric constant, and to lower the parasitic capacitance at the back surface of the second semiconductor layer 14.

Further, after forming the insulator film 19 on the entire surface of the semiconductor substrate 11, a high temperature annealing at 1000° C. may be carried out. As a consequence, it becomes possible to reflow the insulator film 19, loosen the stress on the insulator film 19, and to reduce the interface level at the border between the insulator film 19 and the second semiconductor layer 14. Further, the insulator film 19 may be formed so as to fill the whole cavity 18 or may be formed leaving part of the cavity 18 unfilled. Furthermore, when filling the cavity 18 between the semiconductor substrate 11 and the second semiconductor layer 14 with the insulator film 19, the semiconductor substrate 11 and the second semiconductor layer 14 may be subjected to heat oxidation.

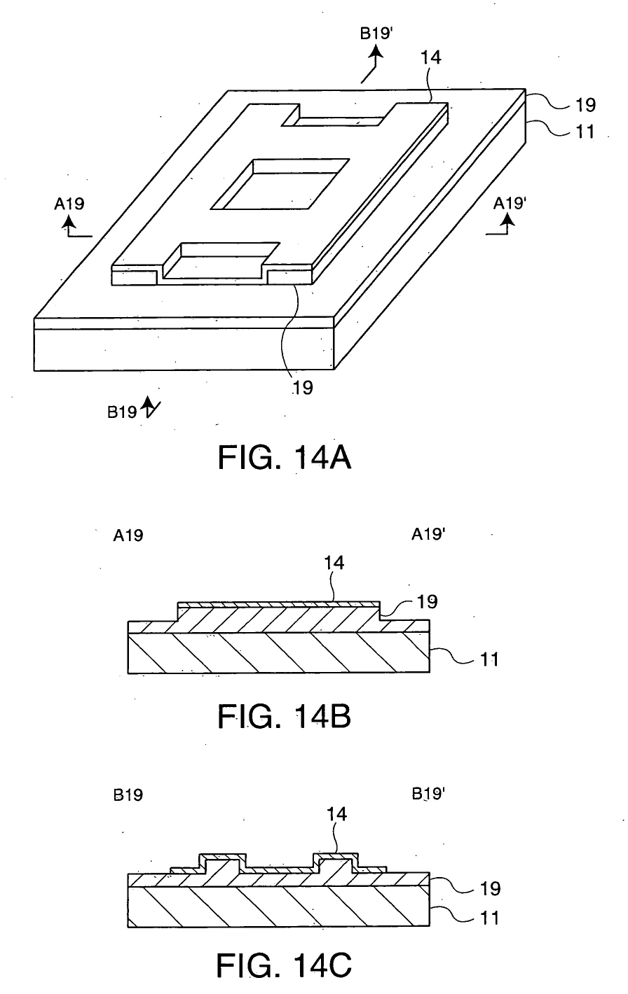

Next, as shown in FIGS. 14A through 14C, the insulating film 19 is thinned by a method such as etch back or chemical mechanical polishing (CMP), thereby exposing the surface of the second semiconductor layer 14 while keeping the insulator film 19 remained on the semiconductor substrate 11.

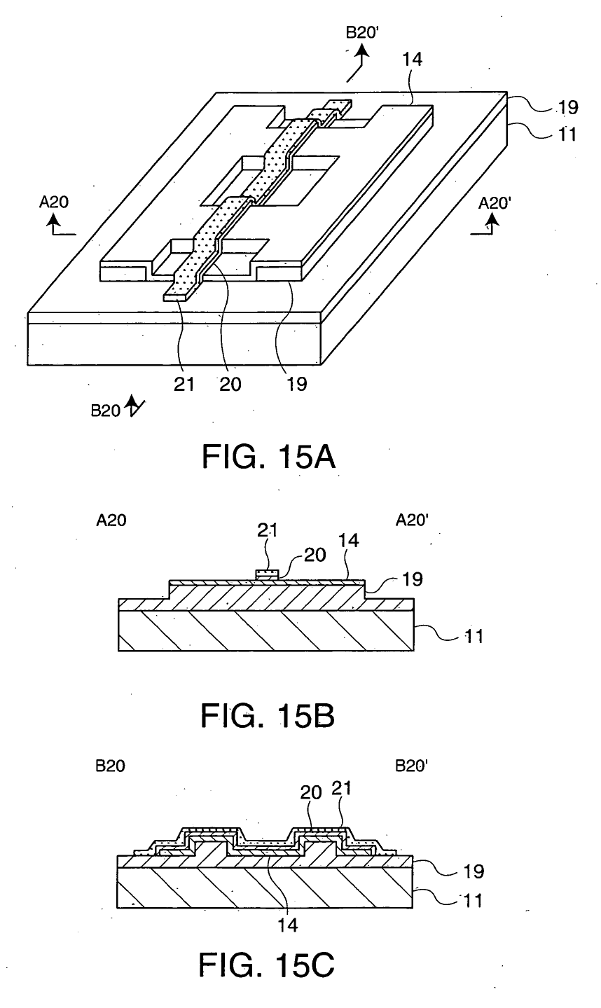

Next, as shown in FIGS. 15A through 15C, a gate insulator film 20 is formed on the surface of the second semiconductor layer 14 by heat-oxidizing the surface of the second semiconductor layer 14. Then, by a method such as CVD, a polycrystalline silicon layer is formed on the second semiconductor layer 5 having the gate insulator film 6 formed thereon. Then, by patterning the polycrystalline silicon layer using the photolithography and etching techniques, a gate electrode 21 is formed on the insulator layer 19 so as to bridge over the second semiconductor layer 14 via the side walls of the second semiconductor layer 14.

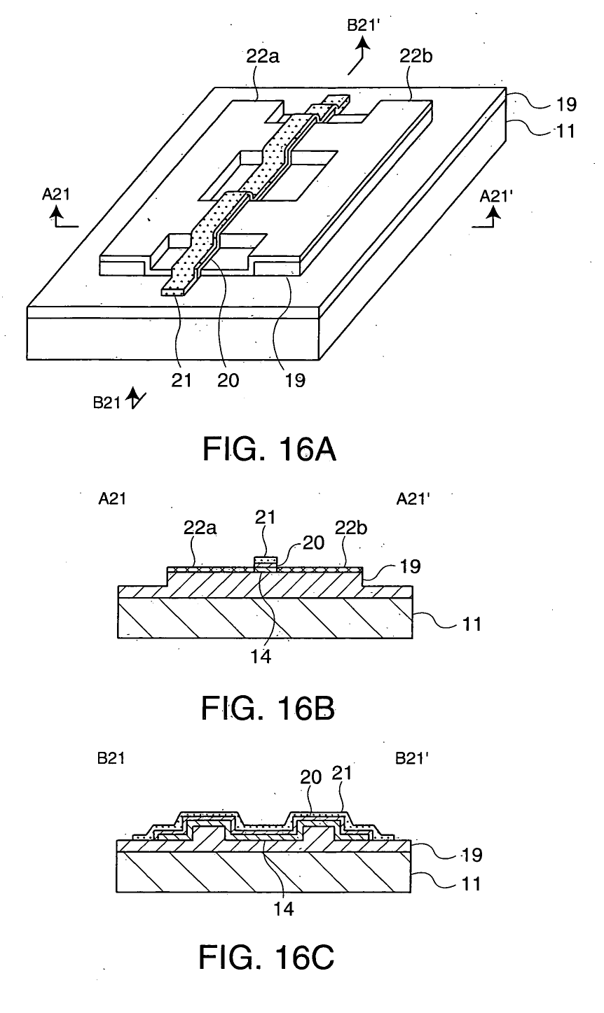

Thereafter, as shown in FIGS. 16A through 16C, by using the gate electrode 21 as a mask and implanting impurity ions such as As, P, or B in the second semiconductor layer 14, source/drain layers 22a and 22b arranged on both sides of the gate electrode 21 are formed on the second semiconductor layer 14.

Consequently, without using the SOI substrate, the epitaxially grown second semiconductor layer 14 can be disposed on the side surfaces of the insulator layer 19, and the channels can lie on the film formation surface of the second semiconductor layer 14 that is undamaged by dry-etching. As a consequence, the transistor integration of the SOI transistor can improve, and stable and good electric characteristics can be acquired while reducing the cost of the SOI transistors.

In the embodiments hereinabove, there is described the method in which the level difference 13 for exposing the side surfaces of the first semiconductor layer 12 is formed on the first semiconductor layer 12 so as to form the second semiconductor layer 14 on the side surfaces of the first semiconductor layer 12 formed on the semiconductor substrate 11. However, a third semiconductor layer may be formed on the side surfaces of the second semiconductor layer by selectively and epitaxially growing the second semiconductor layer on the partial region of the first semiconductor layer and by epitaxially growing the third semiconductor layer on this second semiconductor layer. In this case, if the etching rate of the third semiconductor layer is lower than those of the first and second semiconductor layers, the compositions of the first and second semiconductor layers may be the same or different.

The entire disclosure of Japanese Patent Application No. 2005-054611, filed Feb. 28, 2005 is expressly incorporated by reference herein.

What is claimed is:

1. A semiconductor device, comprising:
a second semiconductor layer formed on a side surface of a first semiconductor by epitaxial growth;
a gate electrode disposed on a film formation surface of the second semiconductor layer;
a source layer formed on the semiconductor layer and disposed on one side of the gate electrode; and
a drain layer formed on the semiconductor layer and disposed on the other side of the gate electrode.

2. The semiconductor device according to claim 1, wherein the first semiconductor layer is a single crystal SiₓGe₁₋ₓ or a single crystal SiₓGe_{y}C_{1-x-y}, and the second semiconductor layer is a single crystal Si.

3. The semiconductor device according to claim 1, wherein the first semiconductor layer is a relaxed single crystal SiₓGe₁₋ₓ or a single crystal SiₓGe_{y}C_{1-x-y}, and the second semiconductor layer is a distorted single crystal Si.

4. A semiconductor device, comprising:
a semiconductor layer disposed on a side surface of an insulator layer and formed by epitaxial growth;
a gate electrode formed on a film formation surface of the semiconductor layer;
a source layer formed on the semiconductor layer and disposed on one side of the gate electrode; and
a drain layer formed on the semiconductor layer and disposed on the other side of the gate electrode.

5. A method for manufacturing a semiconductor device, comprising:
exposing a side surface of a first semiconductor layer by patterning the first semiconductor layer formed on an insulator;
forming a second semiconductor layer on the side surface of the first semiconductor layer by epitaxial growth;
forming a gate electrode on a film formation surface of the second semiconductor layer; and
forming a source layer disposed on one side of the gate electrode and a drain layer disposed on the other side of the gate electrode on the second semiconductor layer.

6. A method for manufacturing a semiconductor device, comprising: relaxing a first semiconductor layer formed on an insulator;
exposing a side surface of the first semiconductor layer by patterning the first semiconductor layer;
forming a second semiconductor layer by epitaxial growth on a side surface of the relaxed first semiconductor layer;
forming a gate electrode on a film formation surface of the second semiconductor layer; and
forming a source layer disposed on one side of the gate electrode and a drain layer disposed on the other side of the gate electrode on the second semiconductor layer.

7. The method for manufacturing the semiconductor device according to claim 5, further comprising:
attaching the insulator formed on the first semiconductor substrate to the first semiconductor layer formed on the second semiconductor substrate; and
forming the first semiconductor layer formed on the insulator by removing the second semiconductor substrate having the first semiconductor layer formed thereon, after attaching the insulator to the first semiconductor layer.

8. A method for manufacturing a semiconductor device, comprising:
forming a first semiconductor layer on a semiconductor substrate by epitaxial growth;
exposing a side surface of the first semiconductor layer by selectively etching the first semiconductor layer;
forming a second semiconductor layer having an etching rate lower than that of the first semiconductor layer on the first semiconductor layer having the side surface exposed thereon;
forming a support which is composed of a material whose etching rate Is lower than that of the first semiconductor layer and which supports the second semiconductor layer on the semiconductor substrate;
forming an exposure portion that exposes a part of the first semiconductor layer from the second semiconductor layer;
forming a cavity between the semiconductor substrate and the second semiconductor layer by selectively etching and removing the first semiconductor layer via the exposure portion;
forming a filling insulator layer filled in the cavity;
forming a gate electrode on a film formation surface of the second semiconductor layer disposed on the side surface of the first semiconductor layer; and
forming a source layer disposed on one side of the gate electrode and a drain layer disposed on the other side of the gate electrode on the second semiconductor layer.

9. A method for manufacturing a semiconductor device, comprising:
forming a first semiconductor layer on a semiconductor substrate by epitaxial growth;
forming a second semiconductor layer disposed on a partial region of the first semiconductor layer by selective epitaxial growth;
forming a third semiconductor layer having an etching rate lower than those of the first and second semiconductor layers on the second semiconductor layer by epitaxial growth so as to cover a side surface of the second semiconductor layer;
forming a support which is composed of a material whose etching rate is lower than those of the first and second semiconductor substrates and which supports the third semiconductor layer on the semiconductor substrate;
forming an exposure portion that exposes a part of the first or the second semiconductor layer from the third semiconductor layer;
forming a cavity between the semiconductor substrate and the third semiconductor layer by selectively etching and removing the first and second semiconductor layers via the exposure;
forming a filling insulator layer filled in the cavity;
forming a gate electrode on a film formation surface of the third semiconductor layer formed on the side surface of the second semiconductor layer; and
forming a source layer disposed on one side of the gate electrode and a drain layer disposed on the other side of the gate electrode on the third semiconductor layer.
